(19) United States
(12) Patent Application Publication
(10) Pub. No.: US 2012/0062042 A1
(43) Pub. Date: Mar. 15, 2012

(54) LOW POWER START-UP CIRCUIT

(76) Inventor: David M. Burke, Taylor, MI (US)

(21) Appl. No.: 12/879,342

(22) Filed: Sep. 10, 2010

(51) Int. Cl. H01H 47/00; H03K 17/687

(52) U.S. Cl. 307/130; 327/427

(57) ABSTRACT

A start-up circuit includes an energy storage device operable to selectively power a load. A switch controls a flow of current from the energy storage device to the load. The switch preventing a flow of current to the load in an OFF state. A voltage comparison device is configured to turn the switch ON to permit a flow of current to the load in response to a charge of the energy storage device exceeding a predefined voltage threshold. The voltage comparison device maintains the switch in an OFF state in response to the charge of the energy storage device being below the predefined voltage threshold.

### BACKGROUND OF THE INVENTION

This disclosure relates to low voltage loads, and more particularly to a low power start-up circuit.

Many circuit elements have a minimum operating voltage that is required for them to run reliably, and this minimum operating voltage may be greater at startup than in a normal operating state. For example, solar cells that power a load may only be able to provide 20-80 uA peak current at some light levels. However, some devices have startup current requirements of 1-3 mA.

### SUMMARY

A start-up circuit includes an energy storage device operable to selectively power a load. A switch controls a flow of current from the energy storage device to the load. The switch preventing a flow of current to the load in an OFF state. A voltage comparison device is configured to turn the switch ON to permit a flow of current to the load in response to a charge of the energy storage device exceeding a predefined voltage threshold. The voltage comparison device maintains the switch in an OFF state in response to the charge of the energy storage device being below the predefined voltage threshold.

These and other features of the present invention can be best understood from the following specification and drawings, the following of which is a brief description.

### BRIEF DESCRIPTION OF THE DRAWINGS

FIG. 1 schematically illustrates an example low power start-up circuit.

### DETAILED DESCRIPTION

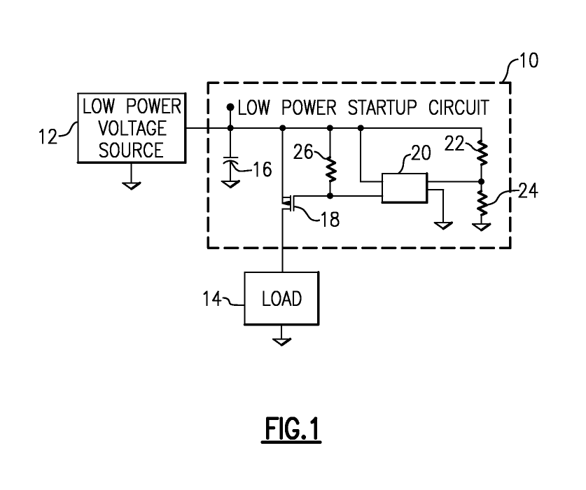

FIG. 1 schematically illustrates an example low power start-up circuit 10 that controls a flow of current from a voltage source 12 to a load 14.

In one example the voltage source 12 is a low power voltage source, such as an energy harvesting device (e.g., solar cell, thermoelectric device, mechanical energy harvester, etc.). The load 14 may include an occupancy sensor, for example. Of course, other voltage sources and loads could be used.

The start-up circuit 10 includes an energy storage device (“ESD”) 16, a switch 18, and a comparator 20. The ESD is charged by the voltage source 12. Although the energy storage device 16 is illustrated as being a capacitor, it is understood that this is only an example, and the energy storage device could include additional or other components.

The switch 18 controls a flow of current between the voltage source 12 and the load 14. The comparator 20 is configured to only turn the switch 18 ON in response to a charge of the ESD 16 exceeding a predefined voltage threshold, and is configured to maintain the switch 18 in an OFF state in response to the charge of the ESD 16 being below the predefined voltage threshold.

As the ESD 16 charges, the comparator 20 compares the charge of the ESD 16 to the predefined voltage threshold. If the ESD 16 voltage remains below the predefined voltage threshold, the switch 18 is maintained in an OFF state to prevent a flow of current from the ESD 16 to the load 14. If the ESD 16 voltage becomes greater than or equal to the predefined voltage threshold, the comparator 20 turns ON the switch 18 enabling current to flow to the load 14.

The predefined voltage threshold may be selected to satisfy both a required runtime voltage of the load 14 and a potentially greater required startup voltage of the load 14. In one example the load 14 is a low voltage occupancy sensor and the predefined voltage threshold is set to be 2 Volts such that the ESD 16 is able to meet startup and runtime voltage requirements of the occupancy sensor. Of course, other thresholds and loads could be used.

The resistor 26 acts as a pull-up resistor, and ensures that the comparator 20 does not erroneously produce a logic low output. The resistors 22, 24 are arranged as a voltage divider, are connected to an input of the comparator 20, and determine the predefined voltage threshold. In one example the comparator 20 has a threshold of 1.24 Volts in order to achieve the overall system predefined voltage threshold of 2 Volts.

In one example the switch 18 is an “active low” switch (e.g. a p-channel FET) such that the switch 18 only turns on if a logic low signal is applied to its gate. The “active low” configuration offers the benefit of compensating for hardware limitations of some comparators which do not guarantee their operation at low voltages, and may undesirably turned ON beneath the predefined voltage threshold. However, it is understood that the switch 18 does not have to be an active low switch, and it is understood that an active high switch could be used.

$${V}_{LIMIT} = {V}_{ref} * [ 1 + \frac{{R}_{1}}{{R}_{2}} ]$$

where V_{LIMIT} is the predefined voltage threshold;
V_{ref} is an internal threshold voltage of the comparator 20 corresponding to a voltage level at which the comparator changes its output from high to low or from low to high;
R₁ is a resistance of the resistor 22;
R₂ is a resistance of the resistor 24.

Thus, the start-up circuit 10 ensures that a flow of current to the load 14 can be prevented unless the ESD 16 voltage is sufficient for runtime or startup requirements of the load 14.

Although a comparator has been described as performing the task of comparing the voltage of the energy storage device 16 to the predefined threshold, it is understood that this is only an example, and that other devices (e.g. a microcontroller) could perform this task.

Although embodiments of this invention have been disclosed, a worker of ordinary skill in this art would recognize that certain modifications would come within the scope of this invention. For that reason, the following claims should be studied to determine the true scope and content of this invention.

What is claimed is:

1. A start-up circuit, comprising:
a switch controlling a flow of current from a capacitor to a load, the switch having an active low input; and
a comparator operable to turn the switch ON in response to a charge of the capacitor exceeding a predefined voltage threshold.

2. The circuit of claim 1, including an energy harvesting power source operable to be charged from environmental conditions, and operable to charge the capacitor.

3. The circuit of claim 2, wherein the power source includes at least one of a solar cell, a thermoelectric device, or a mechanical energy harvester.

4. The circuit of claim 1, including:
a plurality of resistors configured to act as a voltage divider, the plurality of resistors being electrically connected to an input of the comparator, and the plurality of resistors determining the predefined voltage threshold.

5. The circuit of claim 4, wherein the plurality of resistors are chosen to set a predefined voltage threshold that is sufficient to satisfy both a required runtime voltage of the load and a required startup voltage of the load, the required startup voltage being greater than the required runtime voltage.

6. The circuit of claim 1, wherein the switch is an active low input switch.

7. A start-up circuit, comprising:
an energy storage device operable to selectively power a load;
a switch controlling a flow of current from the energy storage device to the load, the switch preventing a flow of current to the load in an OFF state; and
a voltage comparison device configured to turn the switch ON to permit a flow of current to the load in response to a charge of the energy storage device exceeding a predefined voltage threshold, and the voltage comparison device maintaining the switch in an OFF state in response to the charge of the energy storage device being below the predefined voltage threshold.

8. The circuit of claim 7, wherein the voltage comparison device includes at least one of a comparator or a microcontroller.

9. The circuit of claim 7, including:
an energy harvester operable to harvest energy from environmental conditions, and operable to charge the energy storage device.

10. The circuit of claim 9, wherein the energy harvester includes at least one of a solar cell, a thermoelectric device, or a mechanical energy harvester.

11. The circuit of claim 7, wherein the energy storage device includes a capacitor.

12. The circuit of claim 7, including:
a plurality of resistors configured to act as a voltage divider, the plurality of resistors being electrically connected to an input of the comparator, and the plurality of resistors determining the predefined voltage threshold.

13. The circuit of claim 7, wherein the predefined voltage threshold is chosen to be sufficient to satisfy both a required runtime voltage of the load and a required startup voltage of the load, the required startup voltage being greater than the required runtime voltage.

14. The circuit of claim 7, wherein the switch is an active low input switch.

15. The circuit of claim 14, wherein the active low input switch is a P-channel FET.

16. A method of providing start-up current to a load, comprising:
comparing a charge of an energy storage device to a predefined voltage threshold, the energy storage device being connected to a load via a switch;
maintaining the switch in an OFF state in response to the charge of the energy storage device being below a predefined voltage threshold; and
turning the switch ON to permit a flow of current to the load in response to a charge of the energy storage device exceeding the predefined voltage threshold.

17. The method of claim 16, including:
charging the energy storage device using energy harvested from environmental conditions via an energy harvester.

18. The method of claim 16, wherein the energy harvester includes at least one of a solar cell, a thermoelectric device, or a mechanical energy harvester, and wherein the energy storage device includes a capacitor.

19. The method of claim 16, wherein the predefined voltage threshold is chosen to be sufficient to satisfy both a required runtime voltage of the load and a required startup voltage of the load, the required startup voltage being greater than the required runtime voltage.

20. The method of claim 16, wherein the switch is an active low input switch.
